(19) United States
(12) Patent Application Publication
(10) Pub. No.: US 2026/0172006 A1
(43) Pub. Date: Jun. 18, 2026

(54) HYSTERETIC CIRCUITS

(71) Applicant: Cirrus Logic International Semiconductor Ltd., Edinburgh (GB)

(72) Inventors: John P. LESSO, Edinburgh (GB); Andrew J. HOWLETT, Edinburgh (GB)

(73) Assignee: Cirrus Logic International Semiconductor Ltd., Edinburgh (GB)

(21) Appl. No.: 19/410,757

(22) Filed: Dec. 5, 2025

Related U.S. Application Data
(60) Provisional application No. 63/735,217, filed on Dec. 17, 2024.

(51) Int. Cl. H03K 3/0231; H03L 7/099

(52) U.S. Cl. CPC H03K 3/0231; H03L 7/099

(57) ABSTRACT

An integrated circuit (IC) comprising: a digital interface terminal; and processing circuitry, wherein the IC is operable in: a first mode in which the digital interface terminal operates as a digital input or output terminal for communication with the integrated circuit; and a second mode in which the digital interface terminal operates as a hysteretic terminal for coupling with circuitry external to the IC to implement a hysteretic circuit.

### FIELD OF THE INVENTION

The present disclosure relates to hysteretic circuits.

### BACKGROUND

Hysteretic circuits (i.e. circuits that use or exploit hysteresis in one or more components) are known. One example of such a known hysteretic circuit is a circuit that uses hysteresis to generate an oscillating signal. For example, time-encoding machines or modulators (TEMs) and synchronous TEMs (STEMs) may use an oscillating signal generated using a hysteretic component such as a hysteretic comparator to generate a time-encoded signal based on a received input signal.

One application of TEMs and STEMs is in sensing circuitry. In such circuitry, a time-encoded signal is generated by a TEM or STEM based on a varying impedance such as a variable resistance or capacitance, such that a physical property associated with the varying impedance can be monitored. A resistive button press sensor or capacitive touch sensor may employ a TEM or STEM in this way, for example.

FIG. 1 is a schematic representation of example sensing circuitry based on a STEM. Such sensing circuitry is described in U.S. Pat. No. 11,031,940, the contents of which are incorporated by reference herein.

The sensing circuitry of FIG. 1, shown generally at 100, is configured to output a signal indicative of the capacitance of a capacitive component 110 (e.g. a capacitive touch sensor component or the like), which is represented in FIG. 1 as a variable capacitor.

The sensing circuitry 100 includes a hysteretic comparator 120 having a first input which, in use, receives a reference voltage VREF and a second input which, in use, receives a feedback signal SFB. An output of the hysteretic comparator 120 is coupled to an input of a latch 130.

An output of the latch 130 is coupled to a first terminal of a resistor (or other resistive component) 140. A second terminal of the resistor 140 is coupled to a first terminal of the capacitive component 110. A second terminal of the capacitive component 110 is coupled to a ground (or other reference voltage) rail or connection. The resistor 140 and capacitive component 110 thus form a loop filter. A feedback node 112 between the resistor 140 and the capacitive component 110 is coupled to the second input of the hysteretic comparator 120 to supply the feedback signal SFB to the second input of the hysteretic comparator 120. The hysteretic comparator 120, latch 130 and loop filter together form an oscillator that outputs an oscillating signal SOSC.

The output of the latch 130 is also coupled to an input of a counter 150. The latch 130 and the counter 150 receive a common clock signal CLK. An output of the counter 150 is coupled to an input of an estimator 160 which is configured to generate an output signal CEST indicative of the capacitance of the capacitive component 110, based on an output signal of the counter 150. The counter 150 and estimator 160 together form a decoder 170 configured to receive the oscillating signal SOSC output by the oscillator formed by the hysteretic comparator 120, latch 130 and loop filter and output the signal CEST indicative of the capacitance of the capacitive component 110.

In operation of the sensing circuitry 100, the hysteretic comparator 120 compares the feedback signal SFB received at its second input to the reference voltage VREF received at its first input to generate a comparator output signal which can take either a high value (e.g. if the reference voltage VREF is greater than a voltage of the feedback signal SFB) or a low value (e.g. if the reference voltage VREF is less than the voltage of the feedback signal SFB).

The latch 130 receives the comparator output signal and latches its output at either a high signal level or a low signal level. However, the output of the latch 130 changes in synchronisation with the clock signal CLK. Thus, if the output of the latch 130 is at the high signal level when the comparator output signal goes low, the output of the latch 130 only changes to the low signal level in synchronisation with the next clock pulse (e.g. in synchronisation with the next rising or falling edge of the clock signal CLK).

When the output of the latch 130 is high, the capacitive component 110 charges up through the resistor 140, thus increasing the voltage of the feedback signal SFB. When the voltage of the feedback signal SFB exceeds the reference voltage VREF by a threshold defined by the hysteresis of the hysteretic comparator 120, the comparator output signal changes from high to low, and the output of the latch 130 then changes from high to low in synchronisation with the next clock pulse.

When the output of the latch 130 is low, the capacitive component 110 discharges, thus reducing the voltage of the feedback signal SFB. When the voltage of the feedback signal SFB falls below the reference voltage VREF by a threshold defined by the hysteresis of the hysteretic comparator 120, the comparator output signal changes from low to high, and the output of the latch 130 then changes from low to high in synchronisation with the next clock pulse.

An oscillating signal SOSC having a frequency that is dependent (at least in part) upon the capacitance of the capacitive component 110 is thus output by the latch 130. The counter 150 and estimator 160 measure the frequency of the oscillating signal SOSC. The estimator 160 generates the output signal CEST indicative of the capacitance of the capacitive component 110 based on the measured frequency of the oscillating signal SOSC.

The oscillating signal SOSC in the sensing circuitry 100 has an oscillation frequency f_{osc} defined by the relationship:

$${f}_{osc} = \frac{1 - {μ}^{2}}{4 ( {T}_{d} + hRC )} , \qquad ( 1 )$$

where h is the hysteresis of the hysteretic comparator 120, μ=VREF/VDD (where VDD is the supply voltage to the sensing circuitry 100), T_{d} is a delay associated with the latch 130, R is the resistance of the resistor 140 and C is the capacitance of the capacitive component 110.

The relationship above can thus be used by the estimator 160 to determine the capacitance of the capacitive component 110.

In the example illustrated in FIG. 1, the sensing circuitry 100 is configured to output an output signal CEST indicative of the capacitance of the capacitive component 110, but it will be appreciated by those of ordinary skill in the art that if the resistor 140 were replaced by a resistive component having a resistance that is variable in response to some stimulus and the capacitive component 110 were replaced with a fixed capacitor of known capacitance, the output signal of the sensing circuitry 100 would be indicative of the resistance of the resistive component.

### SUMMARY

According to a first aspect, the invention provides an integrated circuit (IC) comprising: a digital interface terminal; and processing circuitry, wherein the IC is operable in: a first mode in which the digital interface terminal operates as a digital input or output terminal for communication with the integrated circuit; and a second mode in which the digital interface terminal operates as a hysteretic terminal for coupling with circuitry external to the IC to implement a hysteretic circuit.

The digital interface terminal may comprise an input terminal, an output terminal or an input/output terminal of the IC.

In the second mode, a portion of the hysteretic circuit may be implemented by the processing circuitry.

In the second mode, the digital interface terminal may be operative as a portion of a hysteretic comparator.

A reference voltage for the hysteretic comparator may be provided by a digital logic threshold of the digital interface terminal.

The hysteretic circuit may comprise a time-encoding modulator (TEM).

The TEM may comprise: an oscillator comprising the digital input terminal, the circuitry external to the IC and a latch; and a decoder, wherein the latch and the decoder are implemented by the processing circuitry.

An impedance of the loop filter may be variable.

The loop filter may comprise a reactive component and a resistive component.

A reactance of the reactive component may be variable in response to a stimulus; or a resistance of the resistive component may be variable in response to a stimulus.

The decoder may be configured to output: an output signal indicative of the reactance of the reactive component; or an output signal indicative of a resistance of the resistive component, based on a frequency of an oscillating signal output by the oscillator.

The IC may comprise an amplifier or CODEC IC.

According to a second aspect, the invention provides a sensing circuit comprising: an oscillator comprising a hysteretic component and a loop filter coupled to the hysteretic component, wherein the oscillator is configured to output an oscillating signal, wherein the loop filter comprises a first component having a variable impedance and a feedback node coupled to the hysteretic component, and wherein the sensing circuit further comprises an input voltage node for receiving an input voltage indicative of a physical quantity to be sensed coupled to the feedback node, the sensing circuit further comprising a decoder configured to receive the oscillating signal and output a first output signal indicative of the impedance of the first component and a second output signal indicative of the input voltage.

An impedance of the loop filter may be variable.

The loop filter may comprise a reactive component and a first resistive component.

A reactance of the reactive component may be variable in response to a stimulus; or a resistance of the first resistive component may be variable in response to a stimulus.

The input voltage node may be coupled to the feedback node by a second resistive component.

A gain of the oscillator may be dependent on a ratio of a resistance of the first resistive component to a resistance of the second resistive component.

The oscillator may comprise a latch.

The decoder may comprise a counter and an estimator.

The latch and the counter may be configured to receive a common clock signal.

A hysteresis of the hysteretic component may be controllable.

A delay associated with the latch may be controllable.

The hysteretic component may comprise a hysteretic comparator.

The hysteretic comparator may comprise a first input for receiving a reference voltage and a second input coupled to the feedback node.

The hysteretic component may comprise a hysteretic digital input or output terminal of an IC.

The IC may further comprise processing circuitry which is configured to implement a latch of the oscillator and the decoder.

The processing circuitry may comprise a digital signal processor (DSP), a microprocessor or a microcontroller.

According to a third aspect, the invention provides time encoding modulator (TEM) circuitry comprising: an integrated circuit (IC) comprising a hysteretic digital input or output terminal and processing circuitry; and a loop filter comprising circuitry external to the IC, wherein the TEM circuitry is implemented by the hysteretic digital input or output terminal, the loop filter and the processing circuitry.

According to a fourth aspect, the invention provides oscillator circuitry comprising: an integrated circuit (IC) having a hysteretic digital interface terminal and processing circuitry; and analog circuitry, external to the IC and coupled to the hysteretic digital interface terminal, wherein the oscillator circuitry is configured to generate an oscillating output signal using the analog circuitry, hysteresis of the hysteretic digital interface terminal and the processing circuitry.

According to a fifth aspect, the invention provides circuitry for simultaneously generating a first output signal indicative of a first quantity and a second output signal indicative of a second quantity that is independent of the first quantity, the circuitry comprising an oscillator comprising a hysteretic component and a loop filter, wherein a limit cycle of the oscillator is dependent at least in part on the first quantity and a duty cycle of the oscillator is dependent at least in part on the second quantity.

According to a sixth aspect, the invention provides use of hysteresis of a digital interface terminal of an integrated circuit (IC) in conjunction with circuitry of the IC and/or circuitry external to the IC to implement an oscillating circuit.

According to a seventh aspect, the invention provides hysteretic circuitry comprising: an integrated circuit (IC) having a hysteretic digital input or output terminal; and circuitry external to the IC coupled to the hysteretic digital input or output terminal.

According to an eighth aspect, the invention provides an integrated circuit (IC) comprising: a digital interface terminal; and processing circuitry, wherein the IC is operable in: a first mode in which the digital interface terminal operates as a digital input or output terminal for communication with the processing circuitry; and a second mode in which the digital interface terminal operates as a hysteretic component of a hysteretic circuit comprising the processing circuitry and circuitry, external to the IC, coupled to the digital interface terminal.

According to a further aspect, the invention provides a host device comprising the IC of the first aspect.

The host device may comprise, for example, a laptop, notebook, netbook or tablet computer, a gaming device, a games console, a controller for a games console, a virtual reality (VR) or augmented reality (AR) device, a mobile telephone, a portable audio player, a portable device, a professional audio device, a mixer, a mixing desk, a sequencer, an audio interface device, an accessory device for use with a laptop, notebook, netbook or tablet computer, a gaming device, a games console a VR or AR device, a mobile telephone, a portable audio player or other portable device.

According to a further aspect, the invention provides a host device comprising the sensing circuit of the second aspect.

The host device may comprise a laptop, notebook, netbook or tablet computer, a gaming device, a games console, a controller for a games console, a virtual reality (VR) or augmented reality (AR) device, a mobile telephone, a portable audio player, a portable device, a professional audio device, a mixer, a mixing desk, a sequencer, an audio interface device, an accessory device for use with a laptop, notebook, netbook or tablet computer, a gaming device, a games console a VR or AR device, a mobile telephone, a portable audio player or other portable device.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is schematic representation of example sensing circuitry based on a synchronous time encoding modulator or machine (STEM);

FIG. 2 is a schematic representation of example circuitry according to the present disclosure;

FIG. 3 is a schematic representation of circuitry that combines STEM-based sensing of a quantity such as capacitance, resistance or impedance with monitoring of an input signal such as a voltage;

FIG. 4 is a schematic representation of alternative circuitry that combines STEM-based sensing of a quantity such as capacitance, resistance or impedance with monitoring of an input signal such as a voltage; and

FIG. 5 is a schematic representation of oscillator circuitry according to the present disclosure.

### DETAILED DESCRIPTION

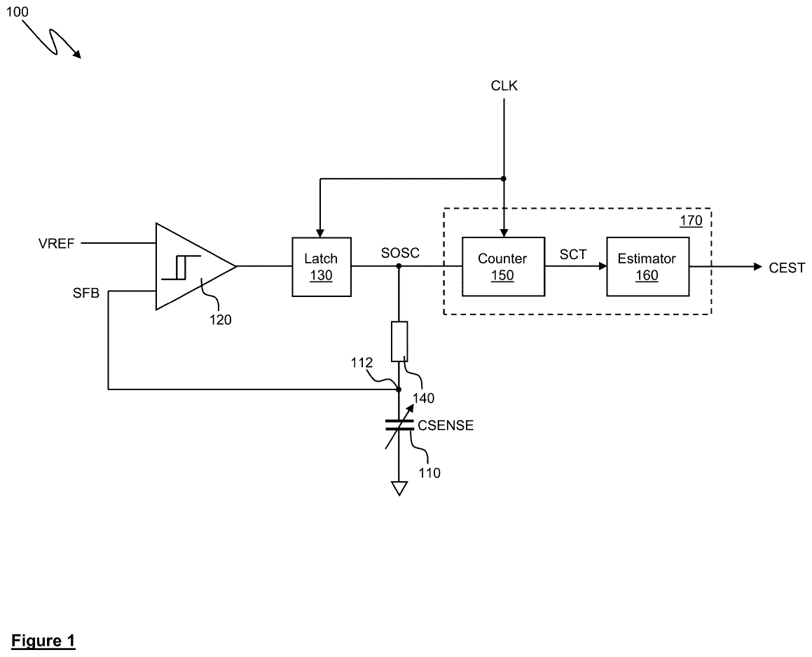

Sensing circuitry 100 of the kind described above with reference to FIG. 1 requires a dedicated hysteretic comparator 120, which may be undesirably costly or large (in terms of silicon area occupied in an integrated circuit implementation).

The present disclosure proposes circuitry that uses hysteresis associated with one or more digital input and/or output terminals of an integrated circuit (IC), e.g. general purpose input/output (GPIO) pins, in conjunction with processing circuitry of the IC and one or more components external to the IC to implement an oscillating circuit, e.g. a TEM or STEM.

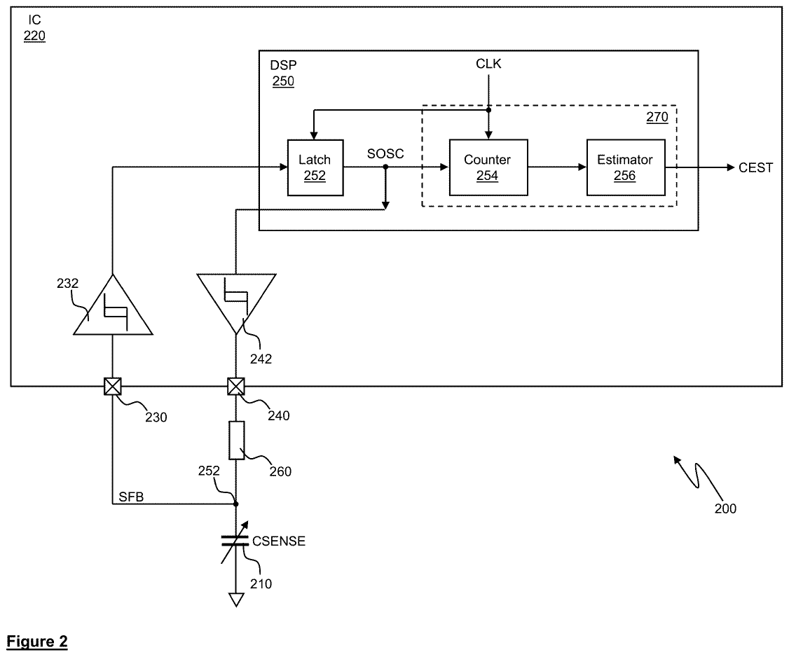

FIG. 2 is a schematic representation of example circuitry according to the present disclosure.

As in the example sensing circuitry 100 of FIG. 1, the example circuitry shown generally at 200 in FIG. 2 implements a STEM-based sensing circuit for measuring or estimating the capacitance of a capacitive component 210, which may be, for example, a capacitive touch sensor component or some other capacitive component having a capacitance that varies in response to some stimulus.

The circuitry 200 of FIG. 2 comprises an integrated circuit (IC) 220 having a digital input terminal 230, a digital output terminal 240 and digital processing circuitry 250, which in this example comprises digital signal processing (DSP) circuitry, but which could equally be processing circuitry of another kind, e.g. a general purpose microprocessor, a microcontroller or any other digital processor or the like. The digital input terminal 230 and the digital output terminal 240 may be, for example, pins, pads or balls for coupling to signal sources external to the IC 220, e.g. conductive tracks or traces on a printed circuit board (PCB) or similar substrate or carrier.

The DSP circuitry 250 is configured (e.g. executes suitable instructions in software or firmware) to implement a latch 252, a counter 254 and an estimator 256 that function in a similar manner to the latch 130, counter 150 and estimator 160 of the sensing circuitry 100 of FIG. 1. The latch 252 and counter 254 receive a common clock signal CLK, which may be generated by the DSP circuitry 250 or by separate clock generator circuitry (not shown in FIG. 2) implemented elsewhere on the IC 220.

The digital input terminal 230 is associated with input hysteresis circuitry 232, which defines one or more hysteresis thresholds (e.g. a low-to-high hysteresis threshold and/or a high-to-low hysteresis threshold) for the digital input terminal 230. Similarly, the digital output terminal 240 is associated with output hysteresis circuitry 242, which defines one or more hysteresis thresholds (e.g. a low-to-high hysteresis threshold and/or a high-to-low hysteresis threshold) for the digital output terminal 240. The input hysteresis circuitry 232 and the output hysteresis circuitry 242 may each comprise Schmitt trigger or Schmitt gate circuitry, for example.

The circuitry 200 includes a resistor (or other resistive component) 260, external to the IC 220, coupled in series with the capacitive component 210 between the digital output terminal 240 and a ground (or other reference voltage) rail or connection that is also external to the IC 220.

A feedback node 262 between the resistor 260 and the capacitive component 210 is coupled to the digital input terminal 230.

In the circuitry 200 of FIG. 2, the hysteresis of the digital input terminal 230 and the hysteresis of the digital output terminal 240 provide an effect similar to that of the hysteretic comparator 120 of the sensing circuitry 100 of FIG. 1. A digital logic threshold of the input terminal 230 and/or a digital logic threshold of the digital output terminal 240 effectively provides an implicit reference voltage equivalent to the reference voltage VREF used in the sensing circuitry 100 of FIG. 1, in the sense that the digital logic threshold is a reference voltage that defines when a transition between logic levels is detected or effected. This implicit reference voltage may be equal to half of a supply voltage to the IC 220, for example. The hysteresis associated with the digital input terminal 230 and/or the digital output terminal 240 provides hysteresis equivalent to that of the hysteretic comparator 120 of the sensing circuitry 100 of FIG. 1.

Thus, the digital input terminal 230 (and its associated hysteresis), the digital output terminal 240 (and its associated hysteresis), the latch 252 and loop filter together form an oscillator that outputs an oscillating signal SOSC. The counter 254 and estimator 256 together form a decoder 270 configured to receive the oscillating signal SOSC output by this oscillator and output a signal CEST indicative of the capacitance of the capacitive component 210.

In operation of the circuitry 200, the digital input terminal 230 receives a feedback signal SFB equal to a voltage across the capacitive component 210. Thus, as the capacitive component 210 charges, a voltage of the feedback signal SFB increases. When the voltage of the feedback signal SFB exceeds the low-to-high hysteresis threshold of the digital input terminal 230, the DSP circuitry 250 recognises that a logic high signal has been received at the digital input terminal 230. In response to this received logic high signal, an output of the latch 252 changes, e.g. from a logic high signal level to a logic low signal level, in synchronisation with the next pulse (e.g. a rising or falling edge of the next pulse) of the common clock signal CLK.

When a voltage of the output of the latch falls below the high-to-low hysteresis threshold of the digital output terminal 240, the digital output terminal 240 transitions to a logic low signal level, and the capacitive component 210 discharges, thus reducing the voltage of the feedback signal SFB. When the voltage of the feedback signal SFB falls below the high-to-low hysteresis threshold of the digital input terminal 230, the DSP circuitry 250 recognises that a logic low signal has been received at the digital input terminal 230. In response to this received logic low signal, the output of the latch 252 changes, e.g. from a logic low signal level to a logic high signal level, in synchronisation with the next pulse (e.g. a rising or falling edge of the next pulse) of the common clock signal CLK. When the voltage of the output of the latch 252 exceeds the low-to-high hysteresis threshold of the digital output terminal 240, the digital output terminal 240 transitions to a logic high signal level, and the capacitive component 210 begins charging through the resistor 260 again.

Thus, an oscillating signal SOSC having a frequency that is dependent (at least in part) upon the capacitance of the capacitive component 210 is output by the latch 252. The counter 254 and estimator 256 measure the frequency of the oscillating signal SOSC. The estimator 256 generates the output signal CEST indicative of the capacitance of the capacitive component 210 based on the measured frequency of the oscillating signal SOSC.

The circuitry 200 of FIG. 2 thus effectively re-purposes the digital input and output terminals 230, 240 of the IC 220 as hysteretic components of an analog circuit, allowing for additional functionality to be provided by the IC over and above the digital functionality for which the IC 220 was designed. As will be appreciated by those of ordinary skill in the art, the circuitry 200 of FIG. 2 provides equivalent functionality to the sensing circuitry 100 of FIG. 1, using the hysteresis of the digital input and output terminals 230, 240 in place of the hysteresis of the hysteretic comparator 120 of the sensing circuitry 100 of FIG. 1.

Thus, in the circuitry 200, the decoder 270 is configured to output an output signal indicative of an impedance of a component of the loop filter (e.g. the capacitance of the capacitive component 210 or the resistance of a resistive component, in an alternative example in which the resistor 260 is replaced by a resistive component having a resistance that is variable in response to some stimulus and the capacitive component 210 is replaced with a fixed capacitor of known capacitance).

The IC 220 may be operable in two modes. In a first mode, the digital input and output terminals 230, 240 operate as digital input and output pins for communication with the DSP circuitry 250. In a second mode, the digital input and output terminals 230, 240 operate as hysteretic terminals (e.g. analog interface terminals having an associated hysteresis), to implement a hysteretic circuit (e.g. analog circuitry that uses hysteresis). In the example described above with reference to FIG. 2, the IC 220 is used to implement STEM-based sensing circuitry, but it will be appreciated that the IC 220 may also be used, in the second mode, to implement other types of hysteretic circuitry, e.g. oscillator circuitry, voltage detection circuitry (e.g. for monitoring a level, state of charge and/or state of health of a battery), current detection circuitry, or circuitry for monitoring a temperature as indicated by an output of a thermistor or other temperature-sensitive circuit element or component.

In one example, the IC 220 may comprise an amplifier IC having integrated DSP circuitry, e.g. an amplifier for driving an actuator (e.g. a resonant actuator) or an audio transducer such as a speaker, headphone or the like. Alternatively, the IC 220 may comprise a CODEC (coder-decoder) for driving a transducer such as a speaker, headphone or the like, or an actuator such as a resonant actuator. The operation of such an amplifier or CODEC IC in the second mode in which input and/or output pins are repurposed as analog interface terminals having internal hysteresis can provide an amplifier or CODEC IC having an integrated sensor channel for monitoring a quantity such as a capacitance or a resistance. An output signal generated by the amplifier IC for driving of any coupled actuator or transducer may be generated at least in part based on the quantity monitored by the sensor channel. For example, STEM-based sensing circuitry may be used to monitor for a touch input on a capacitive touch-sensitive sensor component, or for a force input on a resistive force-sensitive sensor component, and to drive an actuator coupled to an output of the amplifier IC based on receipt or detection of such an input.

Providing an amplifier IC having an integrated sensor channel in this way enables a combined sensor input and output driver to be implemented using a reduced number of components, as compared to a solution that employs separate sensing circuitry and driver circuitry.

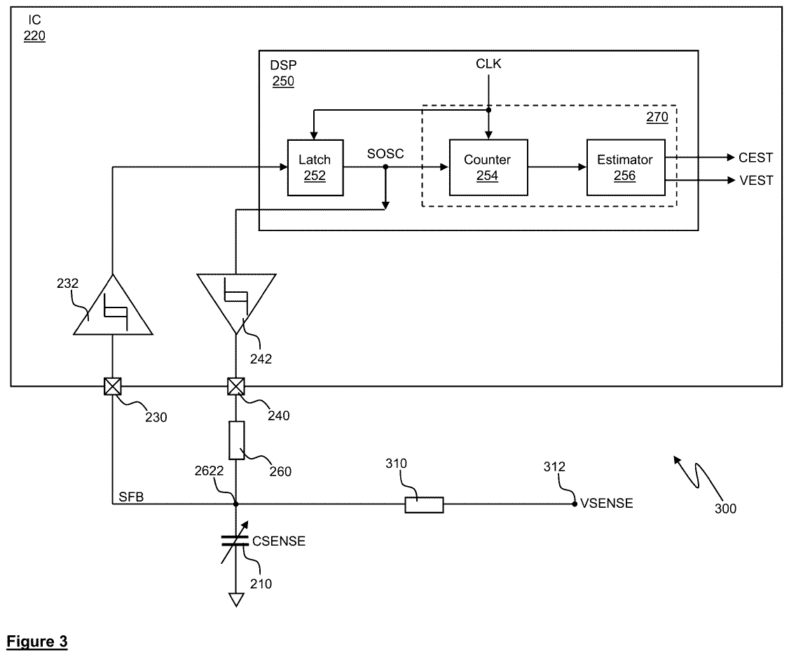

FIG. 3 is a schematic representation of circuitry that combines STEM-based sensing of a quantity such as capacitance, resistance or impedance with monitoring of an input signal such as a voltage.

The circuitry, shown generally at 300 in FIG. 3, includes a number of features in common with the circuitry 200 of FIG. 2. Such common features are denoted by common reference numerals in FIGS. 2 and 3, and will not be described again in detail.

The circuitry 300 of FIG. 3 differs from the circuitry 200 of FIG. 2 in that it includes an additional resistor (or other resistive component) 310, external to the IC 220, having a first terminal coupled to the feedback node 262 and a second terminal coupled to an input voltage node 312 at which an input voltage VSENSE can be received, in use of the circuitry 300. The input voltage VSENSE may be indicative of a physical quantity. For example, the input voltage VSENSE may be provided by a position control system and may be indicative of a position of an actuator or the like. The capacitive component 210 in the circuitry 300 may comprise a capacitive touch-sensitive component, for example.

In use of the circuitry 300, the input voltage VSENSE is added to the feedback signal SFB, such that the feedback signal SFB is modulated by the input voltage VSENSE. Consequently, a duty cycle of the oscillating signal SOSC at the output of the latch 252 is indicative of or encodes the value of the input voltage VSENSE.

Because the duty cycle of the oscillating signal SOSC at the output of the latch 252 is affected only by the input voltage VSENSE (whereas a limit cycle of the circuitry 300 is affected by both a modulation index of the oscillating signal SOSC and the resistance of the resistor 260 and the capacitance of the capacitive component 210 that form the loop filter), it is possible to perform simultaneous measurement of both a first quantity (the capacitance of the capacitive component 210 in the circuitry 300 of FIG. 3) and a second quantity (the input voltage VSENSE in the circuitry 300 of FIG. 3).

It will be appreciated by those of ordinary skill in the art that in an alternative example in which the resistor 260 is replaced by a resistive component having a resistance that is variable in response to some stimulus and the capacitive component 210 is replaced with a fixed capacitor of known capacitance, it would be possible to perform simultaneous measurement of both the resistance of the resistive component (as a first quantity) and the input voltage VSENSE (as a second quantity).

The duty cycle D of the oscillating signal SOSC is defined by the relationship:

$$D = \frac{V SENSE}{V DD} \times \frac{{R}_{ext}}{{R}_{ext 2}} , \qquad ( 2 )$$

where VDD is a supply voltage to the IC 220, Rₑₓₜ is the resistance of the resistor 260 and Rₑₓₜ₂ is the resistance of the additional resistor 310.

The resistance Rₑₓₜ₂ of the additional resistor 310 determines a gain of the circuitry 300. A desired gain can therefore be achieved through the use of an additional resistor 310 of a suitable resistance. In some examples, the additional resistor 310 may be a variable resistor, to permit adjustment of the gain as necessary, e.g. if VSENSE is much larger or much smaller than VDD.

The duty cycle D can be determined by the estimator 256, and the input voltage VSENSE can be calculated or estimated by the estimator 256, based on the duty cycle D, the supply voltage VDD and the resistances Rₑₓₜ and Rₑₓₜ₂ to generate an output signal VEST indicative of the input voltage VSENSE.

A frequency f_{osc} of the oscillating signal SOSC is defined by the relationship:

$${f}_{osc} = \frac{1 - {D}^{2}}{4 ( {T}_{d} + {hR}_{ext} CSENSE )} , \qquad ( 3 )$$

where h is the hysteresis of the digital input and output terminals, T_{d} is a delay associated with the latch 252, Rₑₓₜ is the resistance of the resistor 260 and CSENSE is the capacitance of the capacitive component 210.

The capacitance CSENSE of the capacitive component can thus be estimated by the estimator 256 using the relationship:

$$CSENSE = \frac{1 - {D}^{2} - 4 {f}_{osc} {T}_{d}}{4 {f}_{osc} {hR}_{ext}} . \qquad ( 4 )$$

Thus, in the circuitry 300, the decoder 270 is configured to output a first output signal indicative of an impedance of a component of the loop filter (e.g. the capacitance of the capacitive component 210 or the resistance of a resistive component, in an alternative example in which the resistor 260 is replaced by a resistive component having a resistance that is variable in response to some stimulus and the capacitive component 210 is replaced with a fixed capacitor of known capacitance) and a second output signal indicative of the input voltage VSENSE.

The circuitry 300 uses the hysteresis of the digital input and/or output terminals 230, 240 of the IC 220 in combination with the DSP circuitry 250 of the IC 220 to implement a STEM.

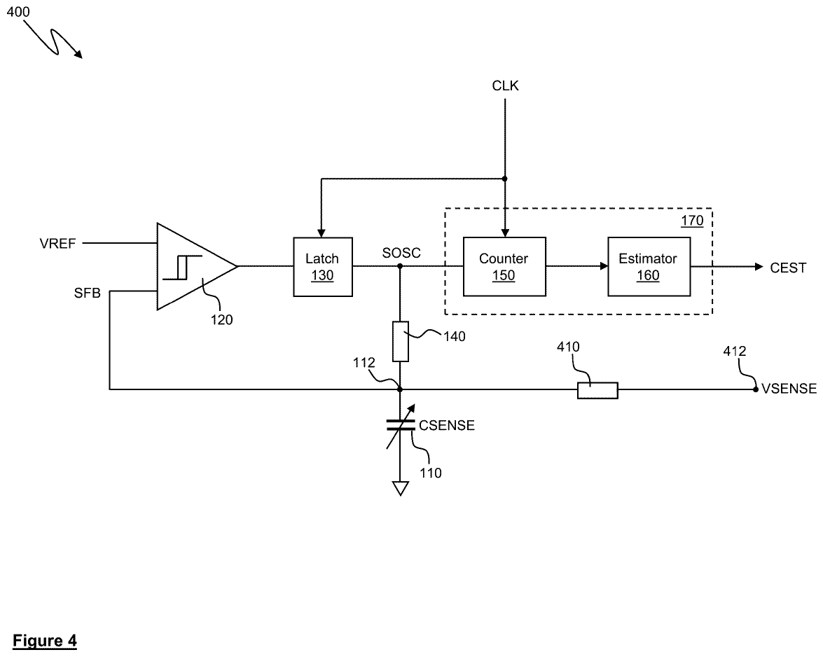

FIG. 4 is a schematic representation of alternative circuitry that combines STEM-based sensing of a quantity such as capacitance, resistance or impedance with monitoring of an input signal such as a voltage, using analog hysteretic comparator circuitry.

The circuitry, shown generally at 400 in FIG. 4, includes a number of features in common with the sensing circuitry 100 of FIG. 1. Such common features are denoted by common reference numerals in FIGS. 1 and 4, and will not be described again in detail.

The circuitry 400 of FIG. 4 differs from the sensing circuitry 100 of FIG. 1 in that it includes an additional resistor (or other resistive component) 410, having a first terminal coupled to the feedback node 112 and a second terminal coupled to an input voltage node 412 at which an input voltage VSENSE can be received, in use of the circuitry 400. As in the circuitry 300 of FIG. 3, the input voltage VSENSE may be indicative of a physical quantity. For example, the input voltage VSENSE may be provided by a position control system and may be indicative of a position of an actuator or the like. The capacitive component 110 in the circuitry 400 may comprise a capacitive touch-sensitive component, for example.

As in the circuitry 300 of FIG. 3, in use of the circuitry 400, the input voltage VSENSE is added to the feedback signal SFB, such that the feedback signal SFB is modulated by the input voltage VSENSE. Consequently, a duty cycle of the oscillating signal SOSC at the output of the latch 130 is indicative of or encodes the value of the input voltage VSENSE.

Because the duty cycle of the oscillating signal SOSC at the output of the latch 130 is affected only by the input voltage VSENSE (whereas a limit cycle of the circuitry 300 is affected by both a modulation index of the oscillating signal SOSC and the resistance of the resistor 140 and the capacitance of the capacitive component 110 that form the loop filter), it is possible to perform simultaneous measurement of both a first quantity (the capacitance of the capacitive component 110 in the circuitry 400 of FIG. 4) and a second quantity (the input voltage VSENSE in the circuitry 400 of FIG. 4).

It will be appreciated by those of ordinary skill in the art that in an alternative example in which the resistor 140 is replaced by a resistive component having a resistance that is variable in response to some stimulus and the capacitive component 110 is replaced with a fixed capacitor of known capacitance, it would be possible to perform simultaneous measurement of both the resistance of the resistive component (as a first quantity) and the input voltage VSENSE (as a second quantity).

The duty cycle D of the oscillating signal SOSC is defined by the relationship:

$$D = \frac{V SENSE}{V DD} \times \frac{{R}_{ext}}{{R}_{ext 2}} , \qquad ( 5 )$$

where VDD is a supply voltage to the hysteretic comparator 120, Rₑₓₜ is the resistance of the resistor 140 and Rₑₓₜ₂ is the resistance of the additional resistor 410.

The resistance Rₑₓₜ₂ of the additional resistor 410 determines a gain of the circuitry 400. A desired gain can therefore be achieved through the use of an additional resistor 410 of a suitable resistance. In some examples, the additional resistor 410 may be a variable resistor, to permit adjustment of the gain as necessary, e.g. if VSENSE is much larger or much smaller than VDD.

The duty cycle D can be determined by the estimator 160, and this the input voltage VSENSE can be calculated or estimated to generate an output signal VEST indicative of the input voltage VSENSE.

A frequency f_{osc} of the oscillating signal SOSC is defined by the relationship:

$${f}_{osc} = \frac{1 - {D}^{2}}{4 ( {T}_{d} + {hR}_{ext} CSENSE )} , \qquad ( 6 )$$

where h is the hysteresis of the hysteretic comparator 120, T_{d} is a delay associated with the latch 130, Rₑₓₜ is the resistance of the resistor 140 and CSENSE is the capacitance of the capacitive component 110.

The capacitance CSENSE of the capacitive component can thus be estimated by the estimator 160 using the relationship:

$$CSENSE = \frac{1 - {D}^{2} - 4 {f}_{osc} {T}_{d}}{4 {f}_{osc} {hR}_{ext}} . \qquad ( 7 )$$

As noted in equations (1), (3), (4), (6) and (7) above, a delay T_{d} may be associated with the latch 130 of the example circuitry shown in FIGS. 1 and 4 and with the latch 252 of the example circuitry shown in FIGS. 3 and 4. This delay may be configurable or adjustable, to compensate for small hysteresis in the hysteretic component (e.g. a small hysteresis threshold of the digital input and/or output terminal 230, 240 in the examples shown in FIGS. 2 and 3, or a small hysteresis threshold of the hysteretic comparator 120 in the example shown in FIG. 4). Additionally, the delay may be modulated to minimise or reduce undesired fluctuation of the limit cycle of the circuitry due to interference. In some examples, acts as a dither to the latch 130, 252, as will be understood by those of ordinary skill in the art.

Additionally or alternatively, the hysteresis of the hysteretic component(s) of the example circuitry shown in FIGS. 2, 3 and 4 may be configurable or adjustable, to permit adjustment of the oscillation frequency of the oscillating signal SOSC. For example, in the examples shown in FIGS. 3 and 4, a low-to-high hysteresis threshold and/or a high-to-low hysteresis threshold of the digital input and/or the digital output terminal 230, 240 may be configurable or adjustable, while in the example shown in FIG. 4, a low-to-high hysteresis threshold and/or a high-to-low hysteresis of the hysteretic comparator 120 may be configurable or adjustable.

Additionally or alternatively, in the examples shown in FIGS. 2 and 3, the hysteresis (e.g. a low-to-high hysteresis threshold or a high-to low hysteresis threshold) of the digital input terminal 230 may be fixed, configurable or adjustable, and the digital output terminal 240 may be configurable to have a fixed, configurable or variable hysteresis, or to have no hysteresis.

In the examples shown in FIGS. 2 and 3, the hysteresis of the digital input terminal 230 and/or the digital output terminal 240 is used to implement STEM-based sensor circuitry for detecting a capacitance, resistance or impedance and, in the example of FIG. 3, an input voltage.

It will be appreciated, however, that the oscillator formed of the digital input terminal 230 (and its associated hysteresis), the digital output terminal 240 (and its associated hysteresis), the latch 252 and loop filter could be used in other applications.

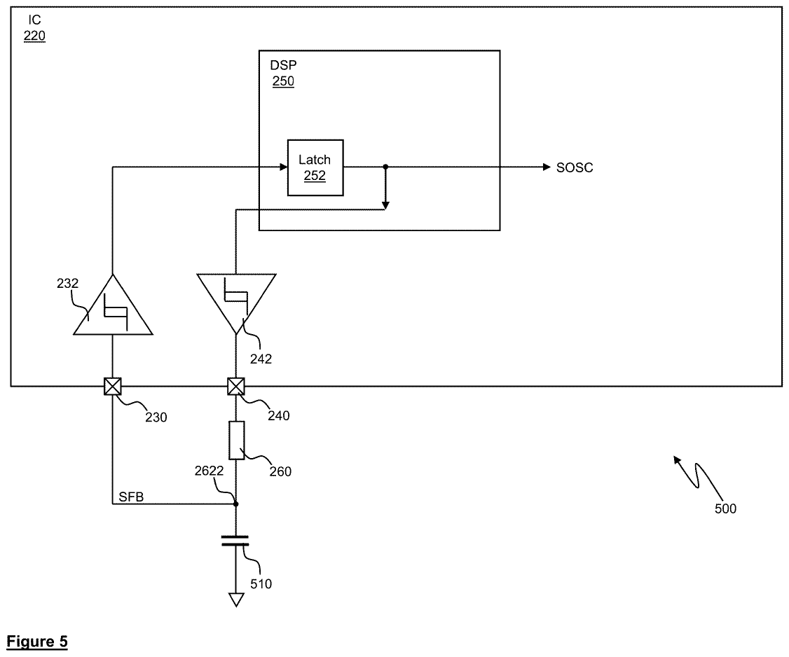

FIG. 5 is a schematic representation of oscillator circuitry according to the present disclosure. The oscillator circuitry, shown generally at FIG. 5 comprises a number of elements in common with the circuitry 200 of FIG. 2. Such common elements are denoted by common reference numerals in FIGS. 2 and 5 and will not be described in detail here.

The oscillator circuitry 500 differs from the circuitry 200 of FIG. 2 in that it omits the decoder formed by the counter and estimator 254, 256, such that the oscillating signal SOSC output by the latch 252 is the output of the oscillator circuitry 500.

The oscillator circuitry 500 further differs from the circuitry 200 of FIG. 2 in that the capacitive component 210 of the circuitry 200 is replaced by a capacitor 510 of fixed capacitance. Thus, the frequency of the oscillating signal SOSC output by the latch is fixed (rather than being variable based on the capacitance of the capacitive component 210), and is dependent upon the capacitance of the capacitor 510, the resistance of the resistor 260, the hysteresis of the digital input terminal 230 and/or the hysteresis of the digital output terminal 240 and any time delay associated with the latch 252. As in the examples described above with reference to FIGS. 2 and 3, the delay associated with the latch 252 may be configurable or adjustable, and the hysteresis of the digital input terminal 230 and/or the digital output terminal 240 may be configurable or adjustable. Additionally or alternatively, the digital output terminal 240 may be configurable to have a fixed, configurable or variable hysteresis, or to have no hysteresis.

The oscillating output signal SOSC output by the oscillator circuitry 500 may be used by downstream circuitry, e.g. as a clock signal for downstream circuitry such as analog to digital converter (ADC) or digital to analog (DAC) circuitry or other circuitry that requires a clock signal. As will be appreciated by those of ordinary skill in the art, the oscillating signal SOSC output by the oscillator circuitry 500 may not be as high quality as a clock signal generated by other types of clock signal generator circuitry such as locked loop circuitry, but may be adequate for applications in which a high quality clock signal is not required.

The examples described above with reference to FIGS. 2, 3 and 5 use a resistor 140, 260 (or other resistive component) coupled to the hysteretic digital output terminal 240 of the IC 220 as part of a loop filter. In other examples, the output hysteresis circuitry 242 may be configured or configurable to provide a constant output current (i.e. the output hysteresis circuitry 242 may be configured or configurable as a constant current output). In such examples the resistor 140, 260 could be omitted, thus reducing the number of off-chip components required.

In the examples shown in FIGS. 2, 3 and 5, the hysteretic digital input terminal 230 and/or the hysteretic digital output terminal 240 of the IC 220 is used as part of an oscillator, but it is to be appreciated that the present disclosure extends to the use of a hysteretic input or output or input/output terminal of an IC in conjunction with circuitry external to the IC to implement hysteretic circuitry.

In the broad sense, there are many ways to realise a relaxation oscillator using a combination of resistive and reactive components, such as using RC (resistive and capacitive) components, LR (inductive and resistive) components, or RLC (resistive, inductive and capacitive) components. In each of these cases, the filter element comprising the resistive component, the capacitive component and/or the inductive component acts as a low-pass filter, which in conjunction with a hysteresis gives rise to a controlled oscillation.

Whilst the embodiments described above focus on an RC implementation, replacing the RC component with LR component would have the same effect. In may be possible that a bond wire inductance of a package may provide at least a portion of the inductance for such an LR-based arrangement. In such a case, only an external resistive component (such as a resistor) may be required, which could be the sense component.

Whilst the examples described above permit detection of the capacitance a capacitive component or the resistance of a resistive component, it will be appreciated that in LR-based arrangements the inductance of the inductive component or the resistance of the resistive component could be detected in a similar manner. Additionally or alternatively, in examples that use an RC, LR or RLC arrangement for the filter element, a reactance of a reactive component (e.g. a capacitive component or an inductive component or a combination of capacitive and inductive components) could be detected in a similar manner.

Aspects of the present disclosure are described in the following statements.

There is provided an IC comprising: a controller, and at least one interface pin coupled with the controller, the interface pin having internal hysteresis, wherein the IC is operable in two modes: a first mode, where the interface pin is operated as a digital input/output (or IO) pin for communication with the controller, and a second mode, where the interface pin is operated as a hysteretic analog I/O pin for coupling with off-chip discrete analog components to implement a circuit with hysteresis.

Preferably, when in the second mode, a portion of the circuit with hysteresis is implemented in the controller.

The controller may be a Digital Signal Processor, a microcontroller, or any other suitable digital processor.

Preferably, when in the second mode, the interface pin is operated as a portion of a hysteretic comparator.

Preferably, the interface pin comprises a General Purpose IO (or GPIO) pin of the IC. The hysteretic characteristic of the interface pin is provided by the internal hysteresis of the GPIO pin.

A reference voltage VREF for the hysteretic comparator may be defined by the threshold for the digital logic of the interface pin, for example half the supply voltage of the IC.

Preferably, when in the second mode, the IC implements a portion of a synchronous Time Encoding Machine (or STEM).

Preferably, the IC implements a STEM-based sensor.

Preferably, a hysteretic comparator of the STEM sensor is provided by the interface pin of the IC.

Preferably, the controller (DSP, microprocessor or other digital processor) implements a latch, a counter, and/or an estimator of the STEM sensor.

Preferably, the IC is arranged to be coupled with a variable impedance via the interface pin, wherein the variable impedance implements a loop filter of the STEM sensor.

Preferably, when in the second mode, the controller (DSP, microprocessor or other digital processor) is arranged to monitor a property of the analog circuit. For example, the processor may be arranged to determine a change in an impedance of one of the off-chip discrete analog components, based on a change in oscillation frequency of the STEM sensor.

The off-chip components may comprise a variable capacitance or a variable resistance.

Preferably, the IC is arranged to generate an output signal, wherein the output signal is generated based at least in part on the monitored property of the analog circuit.

Preferably, the IC comprises a transducer driver, wherein when in the second mode the transducer driver is controlled based at least in part on the monitored property of the analog circuit.

Preferably, the IC comprises an amplifier or a CODEC for driving a transducer, for example an actuator or a loudspeaker.

There is further provided a STEM-based sensor wherein a portion of the STEM loop is implemented in the controller (DSP, microprocessor or other digital processor) of an IC coupled with off-chip components, and wherein the hysteretic comparator of the STEM-based sensor is provided by the internal hysteresis of an interface pin of the IC.

Additionally or alternatively, there is provided a STEM-based sensor circuit for monitoring at least two physical properties or quantities of interest, the STEM-based sensor comprising: an oscillator comprising a hysteretic comparator and a loop filter configured to output an oscillation signal; the loop filter comprising a first component with an electrical property that varies with a first physical property or quantity, such that a time constant of the loop filter depends at least in part on the electrical property of the first component; wherein the loop filter is arranged to receive an input signal indicative of a second physical property or quantity, such that a duty cycle of the oscillation signal depends on an electrical property of the input signal, wherein the circuit further comprises a controller arranged to receive the output of the oscillator and to determine an indication of the first physical property and the second physical property based on the characteristics of the oscillation signal.

Preferably, the loop filter comprises a variable impedance, wherein the impedance value changes in response to the first physical property or quantity.

Preferably, the loop filter comprises a primary resistor and a capacitor, wherein one of the primary resistor or the capacitor comprises the variable impedance.

Preferably, the STEM-based sensor circuit further comprises a secondary resistor coupled with the loop filter, wherein the input signal is received through the secondary resistor.

The input signal may comprise a voltage signal.

The voltage signal can be converted into a current signal via the secondary resistor.

Alternatively, the input signal may comprise a current signal.

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, a professional audio device such as a mixer or mixing desk, sequencer, audio interface device or the like, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. An integrated circuit (IC) comprising:
a digital interface terminal; and
processing circuitry,
wherein the IC is operable in:
a first mode in which the digital interface terminal operates as a digital input or output terminal for communication with the integrated circuit; and a second mode in which the digital interface terminal operates as a hysteretic terminal for coupling with circuitry external to the IC to implement a hysteretic circuit.

2. The IC of claim 1, wherein the digital interface terminal comprises an input terminal, an output terminal or an input/output terminal of the IC.

3. The IC of claim 1, wherein in the second mode, a portion of the hysteretic circuit is implemented by the processing circuitry.

4. The IC of claim 1, wherein in the second mode, the digital interface terminal is operative as a portion of a hysteretic comparator.

5. The IC of claim 4, wherein a reference voltage for the hysteretic comparator is provided by a digital logic threshold of the digital interface terminal.

6. The IC of claim 1, wherein the hysteretic circuit comprises a time-encoding modulator (TEM).

7. The IC of claim 6, wherein the TEM comprises:
an oscillator comprising the digital input terminal, the circuitry external to the IC and a latch; and
a decoder,
wherein the latch and the decoder are implemented by the processing circuitry.

8. The IC of claim 7, wherein an impedance of the loop filter is variable.

9. The IC of claim 8, wherein the loop filter comprises a reactive component and a resistive component, wherein:
a reactance of the reactive component is variable in response to a stimulus; or
a resistance of the resistive component is variable in response to a stimulus.

10. (canceled)

11. The IC of claim 8, wherein the decoder is configured to output:
an output signal indicative of the reactance of the reactive component; or
an output signal indicative of a resistance of the resistive component,
based on a frequency of an oscillating signal output by the oscillator.

12. (canceled)

13. A sensing circuit comprising:
an oscillator comprising a hysteretic component and a loop filter coupled to the hysteretic component, wherein the oscillator is configured to output an oscillating signal,
wherein the loop filter comprises a first component having a variable impedance and a feedback node coupled to the hysteretic component,
and wherein the sensing circuit further comprises an input voltage node for receiving an input voltage indicative of a physical quantity to be sensed coupled to the feedback node,
the sensing circuit further comprising a decoder configured to receive the oscillating signal and output a first output signal indicative of the impedance of the first component and a second output signal indicative of the input voltage.

14. The sensing circuit of claim 13, wherein an impedance of the loop filter is variable.

15. The sensing circuit of claim 14, wherein the loop filter comprises a reactive component and a first resistive component, wherein:
a reactance of the reactive component is variable in response to a stimulus; or
a resistance of the first resistive component is variable in response to a stimulus.

16. (canceled)

17. The sensing circuit of claim 13, wherein the input voltage node is coupled to the feedback node by a second resistive component.

18. The sensing circuit of claim 17, wherein a gain of the oscillator is dependent on a ratio of a resistance of the first resistive component to a resistance of the second resistive component.

19. The sensing circuit of claim 13, wherein the oscillator comprises a latch, wherein the decoder comprises a counter and an estimator, and wherein the latch and the counter are configured to receive a common clock signal.

20.-21. (canceled)

22. The sensing circuit of claim 13, wherein a hysteresis of the hysteretic component is controllable.

23. The sensing circuit of claim 19, wherein a delay associated with the latch is controllable.

24. The sensing circuit of claim 13, wherein the hysteretic component comprises a hysteretic comparator, or wherein the hysteretic component comprises a hysteretic digital input or output terminal of an IC.

25. The sensing circuit of claim 24, wherein the hysteretic comparator comprises a first input for receiving a reference voltage and a second input coupled to the feedback node.

26. (canceled)

27. The sensing circuit of claim 24, wherein the IC further comprises processing circuitry which is configured to implement a latch of the oscillator and the decoder.

28. The sensing circuit of claim 27, wherein the processing circuitry comprises a digital signal processor (DSP), a microprocessor or a microcontroller.

29. Time encoding modulator (TEM) circuitry comprising:
an integrated circuit (IC) comprising a hysteretic digital input or output terminal and processing circuitry; and
a loop filter comprising circuitry external to the IC,
wherein the TEM circuitry is implemented by the hysteretic digital input or output terminal, the loop filter and the processing circuitry.

30.-34. (canceled)

35. A host device comprising the IC of claim 1, wherein the host device comprises a laptop, notebook, netbook or tablet computer, a gaming device, a games console, a controller for a games console, a virtual reality (VR) or augmented reality (AR) device, a mobile telephone, a portable audio player, a portable device, a professional audio device, a mixer, a mixing desk, a sequencer, an audio interface device, an accessory device for use with a laptop, notebook, netbook or tablet computer, a gaming device, a games console a VR or AR device, a mobile telephone, a portable audio player or other portable device.

36. (canceled)

37. A host device comprising the sensing circuit of claim 13, wherein the host device comprises a laptop, notebook, netbook or tablet computer, a gaming device, a games console, a controller for a games console, a virtual reality (VR) or augmented reality (AR) device, a mobile telephone, a portable audio player, a portable device, a professional audio device, a mixer, a mixing desk, a sequencer, an audio interface device, an accessory device for use with a laptop, notebook, netbook or tablet computer, a gaming device, a games console a VR or AR device, a mobile telephone, a portable audio player or other portable device.

38. (canceled)
